(19) United States
(12) Patent Application Publication
(10) Pub. No.: US 2025/0019863 A1
(43) Pub. Date: Jan. 16, 2025

(54) MAGNET FOR SINGLE CRYSTAL PRODUCTION APPARATUS, SINGLE CRYSTAL PRODUCTION APPARATUS, AND METHOD OF PRODUCING SINGLE CRYSTAL

(71) Applicant: SUMCO Corporation, Tokyo (JP)

(72) Inventors: Atsuhiro YAMADA, Tokyo (JP); Ryota SUEWAKA, Tokyo (JP)

(73) Assignee: SUMCO Corporation, Tokyo (JP)

(21) Appl. No.: 18/714,387

(22) PCT Filed: Oct. 25, 2022
(86) PCT No.: PCT/JP2022/039762

§ 371 Date: May 29, 2024

(30) Foreign Application Priority Data
Nov. 30, 2021 (JP) 2021-194947

(51) Int. Cl. C30B 30/04; C30B 15/00; C30B 29/06; H01F 7/06; H01F 7/20

(52) U.S. Cl. CPC C30B 30/04; C30B 15/00; C30B 29/06; H01F 7/064; H01F 7/20

(57) ABSTRACT

To provide a magnet for a single crystal production apparatus in which the degree of freedom in the design of the magnetic field distribution is enhanced even when the arrangement of coils composing the magnet of a single crystal production apparatus is restricted. A magnet for a single crystal production apparatus that pulls up a single crystal while applying a horizontal magnetic field to a material melt for the single crystal received in a crucible, the magnet applying the horizontal magnetic field in the single crystal production apparatus, the magnet including four or more coils 2, the ratio of the height to the width of at least one of the four or more coils 2 exceeding 1, and a control unit that enables the four or more coils 2 to generate magnetic fields independently of each other.

### TECHNICAL FIELD

The present disclosure pertains to a magnet for a single crystal production apparatus, a single crystal production apparatus, and a method of producing a single crystal.

### BACKGROUND

Generally, single crystalline semiconductors, such as those of silicon, are used as substrates for semiconductor devices. One of the typical processes for manufacturing such single crystalline semiconductors is the Czochralski (CZ) method. The CZ method is a technique in which a raw material for a semiconductor is received in a crucible and molten, and then a seed crystal is dipped into the molten raw material for a single crystal. By pulling the seed crystal upward, a single crystal is caused to grow beneath the seed crystal, thereby producing a single crystal.

Generally, quartz crucibles are used as crucibles for receiving the raw material of the single crystal described above. Thus, when the material melt received in the crucible undergoes rapid convection, the content of oxygen dissolved from the quartz crucible increases, resulting in a higher oxygen concentration in the single crystal. To address this, the oxygen concentration in the single crystal is controlled by pulling up the single crystal while applying a horizontal magnetic field to the material melt in the crucible to reduce convection.

FIG. 1 is a diagram illustrating one example of a single crystal production apparatus employing the horizontal magnetic field application technique. A single crystal production apparatus 100 illustrated in this figure comprises, in a chamber 11, a crucible 12 for receiving a raw material (e.g., polycrystalline silicon) for a single crystal 16 (e.g., silicon); a heater 14 for heating the raw material in the crucible 12 to melt it into a material melt 13; a crucible rotation mechanism 15 disposed under the crucible 12 for rotating the crucible 12 in the circumferential direction; a seed crystal holder 18 for holding a seed crystal 17 for growing the single crystal 16; a wire rope 19, to which the seed crystal holder 18 is attached at the end; and a wind-up mechanism 20 for winding up the wire rope 19 to draw the single crystal 16, the seed crystal 17, and the seed crystal holder 18 while rotating the wire rope 19. In addition, a magnet 21 having a plurality of coils 22 for applying a horizontal magnetic field (transverse magnetic field) to the silicon melt 13 in the crucible 12 is disposed outside the chamber 11 at the bottom.

The single crystal 16 can be produced using this single crystal production apparatus 10 as follows. Specifically, at first, a certain amount of a raw material 16 for the single crystal is received in the crucible 12, which is heated by the heater 14 to melt the raw material into a material melt 13. A certain horizontal magnetic field is applied to the material melt 13 by the magnet 21.

The seed crystal 17 held in the seed crystal holder 18 is then dipped in the material melt 13 while the horizontal magnetic field is applied to the material melt 13. The crucible 12 is then rotated at a certain rotational speed by the crucible rotation mechanism 15, and the seed crystal 17 (i.e., single crystal 16) is wound up by the wind-up mechanism 20 while rotating it at a certain rotational speed to pull the seed crystal 17 and the single crystal 16 grown beneath the seed crystal 17. Thus, the single crystal 16 with a certain diameter can be produced.

Annular (bobbin-shaped) coils have been widely used as the coils 22 that compose the above-described magnet 21. For example, PTL 1 discloses a method of producing high-quality semiconductor single crystalline ingots. This method involves the use of magnetic field application means comprising annular coils in an even number that are point-symmetrically arranged. The coils form a magnetic field such that the surface (MGP) where the flux density of the magnetic field becomes maximum is positioned at a certain level above the surface of the semiconductor melt, to thereby apply the magnetic field with a certain intensity to the semiconductor melt at a certain position in the crucible.

### CITATION LIST

### Patent Literature

JP2009173536A

### SUMMARY

### Technical Problem

The distribution of the magnetic field applied to the material melt 13 can be designed by arranging the coils 22 at appropriate positions. However, the positioning of the coils 22 may be restricted due to constraints of the configuration of the apparatus. In such cases, if the coils 22 are circular as disclosed in PTL 1, the width, i.e., the diameter, of the coils 22 may need to be reduced in order to achieve the desired magnetic field distribution.

However, since reducing the diameter of the circular coils also decreases the height of the coils 22 at the same time, the reduction in the height can affect the application of the magnetic field in the height direction to the material melt 13 received in the crucible 12. When the coils 22 that compose the magnet 21 are annular in this manner, there is the problem of a low degree of freedom in the design of the magnetic field distribution to be applied to the material melt 13.

The present disclosure has been conceived of in view of the above problem, and an object thereof is to propose a magnet for a single crystal production apparatus in which the degree of freedom in the design of the magnetic field distribution is enhanced even when the arrangement of coils composing a magnet for a single crystal production apparatus is restricted.

### Solution to Problem

The present disclosure, which solves the aforementioned problem, is as follows.
[1] A magnet for a single crystal production apparatus that pulls up a single crystal while applying a horizontal magnetic field to a material melt for the single crystal received in a crucible, the magnet applying the horizontal magnetic field in the single crystal production apparatus, the magnet comprising:
   four or more coils, a ratio of a height to a width of at least one of the four or more coils exceeding 1; and
   a control unit that enables the four or more coils to generate magnetic fields independently of each other.
[2] The magnet for a single crystal production apparatus according to the above [1], wherein the coil has a hollowed-out rectangular shape.
[3] The magnet for a single crystal production apparatus according to the above [1] or [2], wherein the height is 600 mm or more.
[4] The magnet for a single crystal production apparatus according to any one of the above [1] to [3], wherein, when M represents a magnetic flux density at a center O (0 mm, 0 mm, 0 mm) of a magnetic neutral plane, the magnetic flux density is 0.58×M or greater at a point A (0 mm, 0 mm, −400 mm) and the magnetic flux density is 1.47×M or greater at a point B (400 mm, 0 mm, 0 mm).
[5] A single crystal production apparatus, comprising a crucible for receiving a material melt for a single crystal and the magnet according to any one of the above [1] to [4], which is arranged surrounding the crucible, the apparatus pulling up the single crystal while applying a horizontal magnetic field to the melt by the magnet.
[6] A method of producing a single crystal by the Czochralski method using the single crystal production apparatus according to the above [5], the method comprising:
   pulling up the single crystal while applying a horizontal magnetic field to the material melt by the magnet so that, when M represents a magnetic flux density at a center O (0 mm, 0 mm, 0 mm) of a magnetic neutral plane, the magnetic flux density is 0.58×M or greater at a point A (0 mm, 0 mm, −400 mm) and the magnetic flux density is 1.47×M or greater at a point B (400 mm, 0 mm, 0 mm).
[7] The method of producing a single crystal according to the above [6], wherein the single crystal is a single crystalline silicon.

### Advantageous Effect

According to the present disclosure, it is possible to enhance the degree of freedom in the design of the magnetic field distribution even when the arrangement of coils composing a magnet for a single crystal production apparatus is restricted.

### BRIEF DESCRIPTION OF THE DRAWINGS

In the accompanying drawings:

FIG. 1 is a diagram illustrating one example of a single crystal production apparatus employing the horizontal magnetic field application technique;

FIG. 2 is a diagram illustrating a preferred example of a coil for composing a magnet according to the present disclosure, wherein (a) is an overall view, (b) is a front view, (c) is a side view, and (d) is a bottom view;

FIGS. 3A and 3B illustrate an example of the arrangement of a plurality of coils composing a magnet, where FIG. 3A pertains to a case with four coils and FIG. 3B pertains to a case with 12 coils;

FIG. 4 is a diagram illustrating the relationship between the arrangement of the coils illustrated in FIG. 3A and the magnetic flux density in the regions surrounded by the coils;

FIGS. 5A to 5C are diagrams illustrating the magnetic flux density in the regions surrounded by the coils in the case where Dₐ<D_{b}, where FIGS. 5B and 5C are magnetic flux densities along the x-axis and y-axis directions, respectively;

FIGS. 6A to 6C are diagrams illustrating the magnetic flux density in the regions surrounded by the coils in the case where Dₐ>D_{b}, where FIGS. 6B and 6C are magnetic flux densities along the x-axis and y-axis directions, respectively;

FIGS. 7A to 7C are diagrams illustrating the relationship between the output relationship of the coils illustrated in FIG. 3A and the magnetic flux density in the regions surrounded by the coils, where FIGS. 7B and 7C are magnetic flux densities along the x-axis and y-axis directions, respectively;

FIG. 8 is a diagram illustrating one example of a single crystal production apparatus of the present disclosure;

FIGS. 9A and 9B are diagrams illustrating the locations of the center O, point B, and point C of the magnetic neutral plane, where FIG. 9A is a diagram when the crucible is viewed from the top and FIG. 9B is a diagram when the crucible is viewed from a side;

FIGS. 10A to 10C are charts indicating the variations in the oxygen concentration in the axial direction of single crystalline silicon, where FIG. 10A pertains to Comparative Example, FIG. 10B pertains to Example 1, and FIG. 10C pertains to Example 2; and

FIGS. 11A to 11C are charts indicating the fluctuations over time of the temperature at the solid-liquid interface based on three-dimensional fluid simulation, where FIG. 11A pertains to Comparative Example, FIG. 11B pertains to Example 1, and FIG. 11C pertains to Example 2.

### DETAILED DESCRIPTION

An embodiment of the present disclosure will now be described with reference to the drawings. A magnet for a single crystal production apparatus that pulls up a single crystal while applying a horizontal magnetic field to a material melt for the single crystal received in a crucible, the magnet applying the horizontal magnetic field in the single crystal production apparatus. Here, the magnet comprises four or more coils, the ratio of the height to the width of at least one of the four or more coils exceeding 1, and a control unit that enables the four or more coils to generate magnetic fields independently of each other.

As mentioned above, when the arrangement of coils composing a magnet for a single crystal production apparatus is restricted, using bobbin-shaped coils can pose a problem of a limited degree of freedom in the design of the magnetic field distribution to be applied to the material melt in the crucible. The present inventors have diligently studied means to solve the above-mentioned problem. As a result, we have conceived of configuring the coils composing the magnet to have the ratio of the height to the width exceeding 1, in other words, to have a vertically elongated shape.

In other words, by configuring the coils to have a vertically elongated shape, it becomes possible to address the situation where the arrangement of the coils is restricted due to constraints of the configuration of the apparatus. In this manner, it is possible to mitigate the problem simply by reducing the width of the coils without changing the height of the coils. As a result, when the angle between coils is adjusted to achieve the desired magnetic field distribution, it becomes possible to suppress the impact on the application of the magnetic field in the height direction to the material melt. This enhances the degree of freedom in the design of the magnetic field distribution.

In the course of further studies, however, the present inventors have discovered that simply configuring the coils to have a vertically elongated shape is insufficient to achieve the desired magnetic field distribution. It is important that the magnet has four or more coils, with at least one having a vertically elongated shape, and that a control unit is provided that enables the four or more coils to generate magnetic fields independently of each other. We thus have completed the present disclosure.

As apparent from the above description, the magnet for a single crystal production apparatus according to the present disclosure is characterized by its shape and the control unit that enables the coils to generate magnetic fields independently of each other. Other configurations are not limited, and conventionally known configurations may be used as appropriate. Hereinafter, the magnet according to the present disclosure will be specifically described, but the present disclosure is not limited to the specificality.

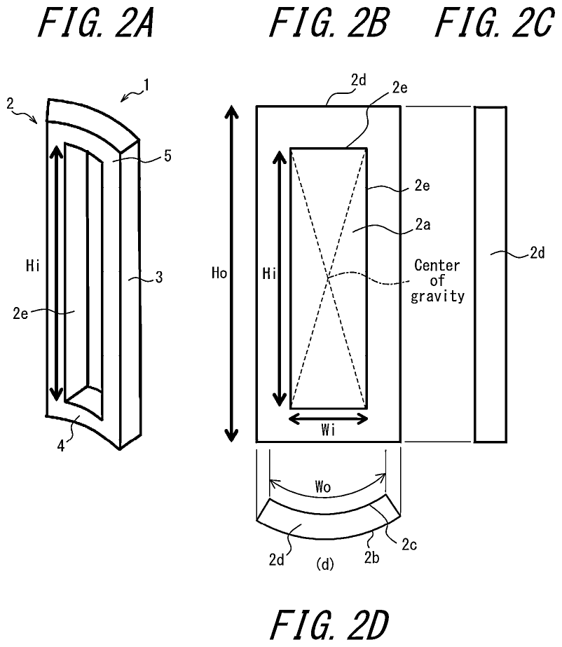

FIG. 2 is a diagram illustrating one preferred example of a coil for composing a magnet for a single crystal production apparatus according to the present disclosure, wherein (a) is an overall view, (b) is a front view, (c) is a side view, and (d) is a bottom view. The coil 2 illustrated in FIG. 2 is configured so that the ratio of the height to the width exceeds 1, in other words, the coil is configured to have a vertically elongated shape. More specifically, the coil 2 for composing the magnet 1 according to the present disclosure has a hollowed-out rectangular shape and has two first portions 3, which are long members extending in the vertical direction, two second portions 4, which are short members extending in the horizontal direction, and four connecting portions 5 each connecting a first portion 3 and a second portion 4.

In the above the coil 2, the length Hi of the first portion 3 is configured to be greater than the length Wi of the second portion 4. As a result, the height of the coil 2 becomes also greater than the width thereof, with the ratio of the height to the width exceeding 1. In the present disclosure, the “height of the coil” refers to the length of the longest part in the up-down direction (vertical direction) of the opening 2a of the hollowed-out shaped coil (denoted as the length Hi of the first portion 3 in FIG. 2), while the “width of the coil” refers to the length of the longest part in the horizontal direction of the opening 2a (denoted as the length Wi of the second portion 4 in FIG. 2). In the case where the coil 2 is curved toward the outer surface 2b as illustrated in FIG. 2(d), the width of the coil 2 is the length along the inner surface 2c of the coil 2. Although the coil 2 for composing the magnet 1 according to the present disclosure is preferably rectangular as illustrated in FIG. 2, it is not limited to rectangular and may be oval, for example. In addition, it is preferable that all of the coils 2 have a vertically elongated shape and have the same shape. This allows for the formation of a highly symmetrical magnetic field distribution.

The coil 2 having such a configuration allows only the width of the coil 2 to be reduced without reducing the height of the coil 2 even when the arrangement of coils 2 is restricted due to the constraints of the apparatus configuration. As a result, the influence on the application of the magnetic field in the height direction to the material melt 13 can be mitigated and the degree of freedom in the design of the magnetic field distribution can be enhanced.

The height of the coil 2 described above is preferably 600 mm or more. This enables effective application of a horizontal magnetic field to the material melt 13 received in the crucible 12 for the production of single crystals having a diameter of 300 mm or more (e.g., having a diameter of 300 to 340 mm in the case of single crystalline silicon for $300 mm wafers, or having a diameter of 451 to 500 mm in the case of single crystalline silicon for $450 mm wafers). In addition, the height of the coil 2 is preferably 750 to 1000 mm for the production of single crystalline silicon for $300 mm wafers, or 1125 to 1500 mm for the production of single crystalline silicon for $450 mm wafers.

Note that the second portions 4 of the coil 2 are preferably curved toward the outer surface 2b of the coil 2, as illustrated in FIG. 2(d). This allows the coils 2 to be arranged along the outer wall of the chamber 11, saving space required for arranging the coils 2 and making the entire magnet 1 to be more compact. Alternatively, the second portions 4 may be configured as straight so that the coil 2 may be flat.

The width Wₒ of the outer shape of the coil 2 (i.e., the length of a second portion 4+the length of two connecting portions 5) is preferably one fourth or less of the circumference L of the magnet 1, more preferably one sixth or less of the circumference L of the magnet 1, more preferably one eighth or less, and most preferably one twelfth or less. By reducing the width Wₒ of the outer shape of the coil 2 relative to the circumference L of the magnet, more coils 2 can be arranged to enhance the degree of freedom in the density of the magnetic flux density among the coils 2 thereby enhancing the degree of freedom in the design of the magnetic field distribution.

In the case where the coil 2 is curved toward the outer surface 2b as illustrated in FIG. 2(d), the width Wₒ of the outer shape of the coil 2 is the length along the inner surface 2c of the coil 2 as illustrated in FIG. 2(d). By reducing the width Wₒ of the outer shape of the coil 2 relative to the circumference L of the magnet, more coils 2 can be arranged to enhance the degree of freedom in the density of the magnetic flux density among the coils 2 thereby enhancing the degree of freedom in the design of the magnetic field distribution. Furthermore, the “circumference of the magnet” refers to the length of the circumference of the circle composed of the inner surfaces 2c of the coils 2 when the magnet 1 is viewed from the top, in the case where the coils 2 are curved toward the outer surface 2b thereof and the inner surfaces 2c of four or more coils 2 make up a circle. Alternatively, in the case where the coils 2 are flat or the inner surfaces 2c of the coils 2 do not make up a circle, the “circumference of the magnet” refers to the length of the circumference of the circle (a circle passing through the four midpoints) made up of the centers of the inner surfaces 2c of the coils 2 (midpoints of line segments corresponding to the inner surfaces 2c) when the magnet 1 is viewed from the top.

In relation to the relationship between the width Wₒ of the above-described coil 2 and the circumference L of the magnet 1, the number of coils 2 is preferably 4 or more. The number of coils 2 to four or more can ensure sufficient degree of freedom in the design of the magnetic field distribution to be applied to the material melt 13 received in the crucible 12. The number of coils 2 is preferably a multiple of 2. When the number of coils 2 is a multiple of 2, the coils 2 can be arranged with high symmetry. The number of coils 2 is more preferably 6 or more, even more preferably 8, and most preferably 12. In addition, the number of coils 2 is preferably 40 or less. This allows a high degree of freedom in the design of the magnetic field while avoiding complex design of the magnetic field, and also reduces the cost of the magnet 1.

The coil 2 may be configured by providing a support having a hollowed-out shape as illustrated in FIG. 2, forming a groove on the outer peripheral surface 2d defining the outer shape of the support or on the inner peripheral surface 2e defining the opening in the support in plan view as illustrated in FIG. 2B, and then winding a wire so as to be received in the groove. Alternatively, the coil 2 may also be formed without using a support by winding the wire into the shape illustrated in FIG. 2 and solidifying the wire with a resin.

Furthermore, in the case where a wire is wound around the outer peripheral surface 2d or the inner peripheral surface 2e of the support, it is preferable that the outer peripheral surface 2d or the inner peripheral surface 2e of the connecting portions 5 composing the coil 2 have a rounded corner (curve) so that the wire for composing the coil 2 is smoothly wound. When no support is used to wind the wire, it is preferable to wind the wire so as to be curved at the parts corresponding to the connection portions 5.

As described above, the magnet 1 according to the present disclosure has four or more coils 2. Each of the four or more coils 2 is connected to a control unit (not illustrated), which can independently control the current value to each coil 2. This allows the respective coils 2 to generate magnetic fields of different strengths and orientations.

It is preferable that the plurality of coils 2 are symmetrically arranged with respect to the axis perpendicular to the axis passing through the center of the magnet 1 and extending in the vertical direction when the magnet 1 is viewed from the top. This allows the formation of a symmetrical magnetic field distribution.

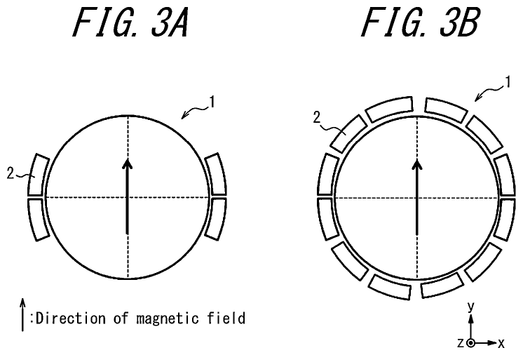

FIG. 3 illustrates one example of the arrangement if the plurality of coils 2 composing the magnet 1 according to the present disclosure, where FIG. 3A illustrates an example where four coils 2 are arranged and FIG. 3B illustrates an example where 12 coils 2 are arranged. Note that the arrows in the figures indicate the direction of the horizontal magnetic field.

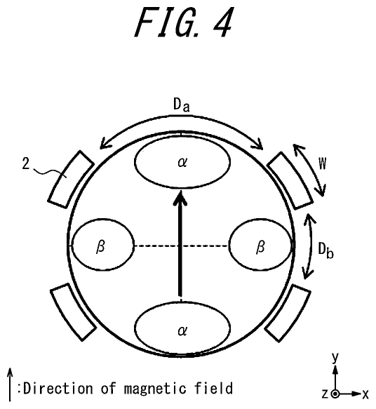

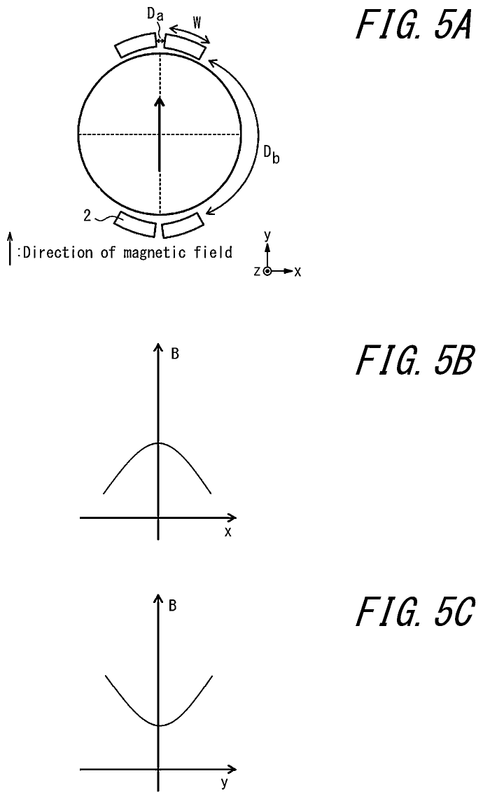

For example, in the case where the magnet 1 comprises four coils 2 as illustrated in FIG. 3A, any desired magnetic field distribution can be set by adjusting the distances between two coils, namely, the distances Dₐ (the distances between two coils without having the xz-plane across them) and the distances D_{b} (the distances between two coils across the xz-plane), as parameters as depicted in FIG. 4. In other words, as the distances Dₐ are reduced, the magnetic flux density in the regions α illustrated in FIG. 4 increases while the magnetic flux density in the regions β decreases. Specifically, as illustrated in FIG. 5A, when Dₐ<D_{b}, the magnetic flux density B decreases along the x-axis direction (FIG. 5B), while the magnetic flux density B increases along the y-axis direction (FIG. 5C), from the center O of the magnetic field.

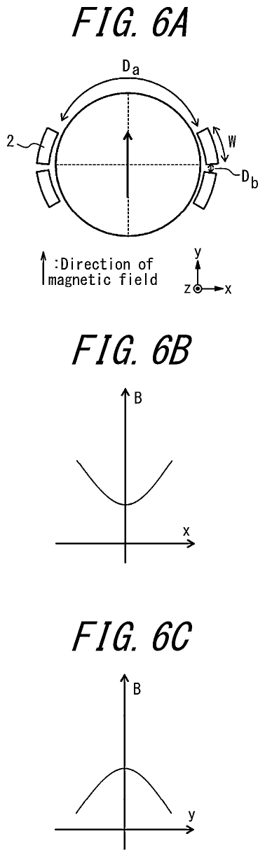

Conversely, as the distance D_{b} is reduced, the magnetic flux density in the regions β illustrated in FIG. 4 increases while the magnetic flux density B in the regions α decreases. Specifically, as illustrated in FIG. 6A, when Dₐ>D_{b}, the magnetic flux density B increases along the x-axis direction (FIG. 6B), while the magnetic flux density B decreases along the y-axis direction (FIG. 6C), from the center O of the magnetic field. In this manner, any desired magnetic field distribution can be set by adjusting the distances Dₐ and D_{b} between two coils 2 as parameters.

Furthermore, in the case where the magnet 1 has 12 coils 2 as illustrated in FIG. 3B, any desired magnetic field distribution can be set by changing the shape of the coils 2, the current value to flow through the coils 2, and the number of turns of the winding wire for forming the coils 2.

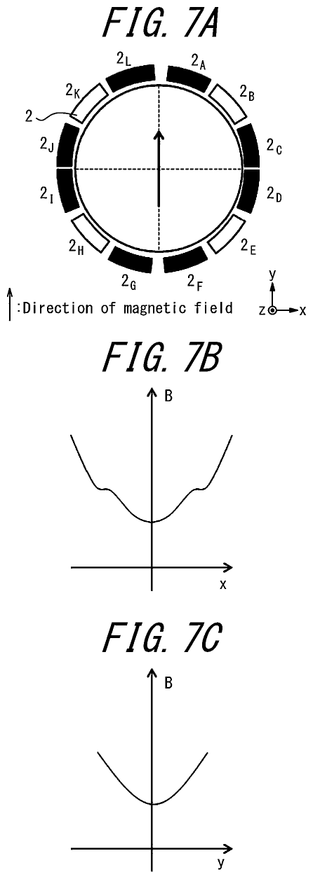

Specifically, as illustrated in FIG. 7A, any desired magnetic field distribution can be set by relatively increasing the output of coils 2_{A}, 2_{E}, 2_{D}, 2_{F}, 2_{G}, 2_{I}, 2_{J}, and 2_{L} and relatively decreasing the output of coils 2_{B}, 2_{E}, 2_{H}, and 2_{K} among the 12 coils 2, to thereby adjust the magnetic flux density along the x-axis (FIG. 7B) and the magnetic flux density along the y-axis (FIG. 7C).

The control unit is preferably configured so that the direction of the current to flow the first coil group consisting of six adjacent coils 2 (coils 2_{J}, 2_{K}, 2_{L}, 2_{A}, 2_{B}, and 2_{C}) is opposite to the direction of the current to flow the second coil group consisting of the remaining six adjacent coils 2 (coils 2_{I}, 2_{H}, 2_{G}, 2_{F}, 2_{E}, and 2_{D}) of the 12 coils 2 illustrated in FIG. 7A. This allows the magnetic field lines of the coils 2 facing each other across the xz-plane to not cancel out, enabling efficient application of magnetic fields to the material melt 13. FIG. 7A illustrates the case where the number of coils is 12. Similarly, in other cases as well where the number of coils is not 12, it is preferable that the first group of coils (coils arranged in the first and second quadrants) and the second group of coils (coils arranged in the third and fourth quadrants) are configured so that the directions of current to flow to the coils 2 are opposite.

Preferably, the control unit is also configured to set different current values to three groups, namely, to the group of 2_{C}, 2_{D}, 2_{I}, and 2_{J}, to the group of 2_{B}, 2_{E}, 2_{H}, and 2_{K}, and to the group 2_{A}, 2_{F}, 2_{G}, and 2_{I}, of the 12 coils 2 illustrated in FIG. 7A, such that the current values are reduced in this order. This can suppress fluctuations of the convection in the material melt 13. FIG. 7A illustrates the case where the number of coils is 12. Similarly, in other cases as well where the number of coils is 6 or more and not 12, it is preferable that the current to flow to coils 2 adjacent to each other across the xz-plane is configured to be larger than the current to the other coils 2.

In addition, the distance between the coil 2_{J} and the coil 2_{I} and the distance between the coil 2_{D} and the coil 2_{D} of the 12 coils 2 illustrated in FIG. 7A are preferably set to be smaller than the distances between other adjacent coils 2. This increases the magnetic flux density gradient near the above-mentioned coils 2 and improves the effect to suppress the fluctuations of the convection. FIG. 7A illustrates the case where the number of coils is 12. Similarly, in other cases as well where the number of coils is not 12, it is preferable that the distance between adjacent coils 2 across the xz-plane is configured to be smaller than the distances between other adjacent coils 2.

The magnet 1 may be an electromagnet (normal conduction) or a superconducting electromagnet, but a superconducting electromagnet is preferred because it can form a stronger magnetic field. When the magnet 1 is configured as a superconducting electromagnet, the winding wire for forming the coil 2 is made of a superconducting material such as a niobium-based alloy. Four or more coils 2 are housed in a cylindrical vacuum vessel (not illustrated) such that two coils 2, for example, are placed so as to face each other. For example, the coils 2 are configured so that the space around the coils 2 is filled with a cooling solvent and the coils 2 are cooled to the transition temperature by a cooling apparatus.

### (Single Crystal Production Apparatus)

A single crystal production apparatus according to the present disclosure comprises a crucible for receiving a material melt for a single crystal and the magnet according to the present disclosure arranged surrounding the crucible, the magnet having four or more coils, the apparatus pulling up the single crystal while applying a horizontal magnetic field to the melt by the magnet.

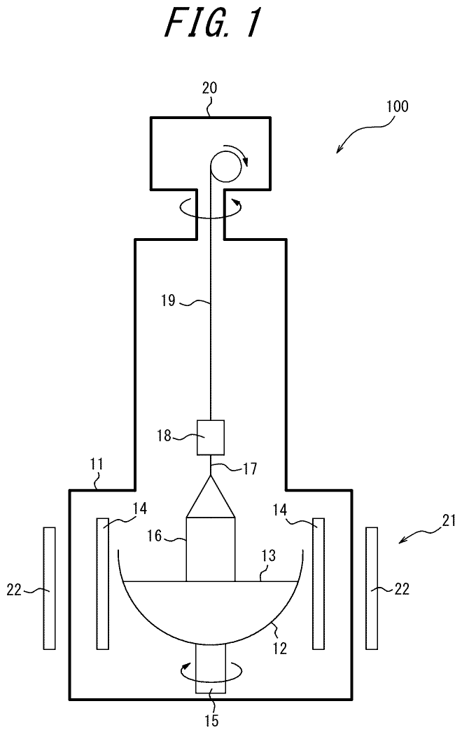

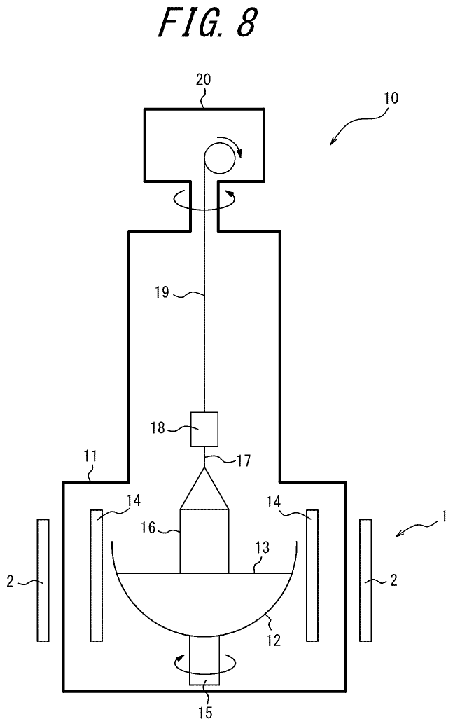

FIG. 8 is a diagram illustrating one example of a single crystal production apparatus according to the present disclosure. Note that the same elements as those in the single crystal production apparatus 100 illustrated in FIG. 1 are denoted by the like reference symbols. Instead of the magnet 21 in the single crystal production apparatus 100 illustrated in FIG. 1, the single crystal production apparatus 10 illustrated in FIG. 8 comprises the magnet 1 according to the present disclosure described above. As described above, the magnet 1 has four or more coils 2 having a ratio of the height to the width exceeding 1. The control unit is configured to enable the four or more coils 2 to generate magnetic fields independently of each other. This allows for an increased degree of freedom in the design of the magnetic field distribution even when the arrangement of coils composing a magnet for a single crystal production apparatus is restricted. The single crystal production apparatus 10 comprising such a magnet 1 is capable of applying a magnetic field to the material melt 13 with a desired magnetic field distribution, thereby producing single crystals with desired characteristics, such as defect-free single crystals.

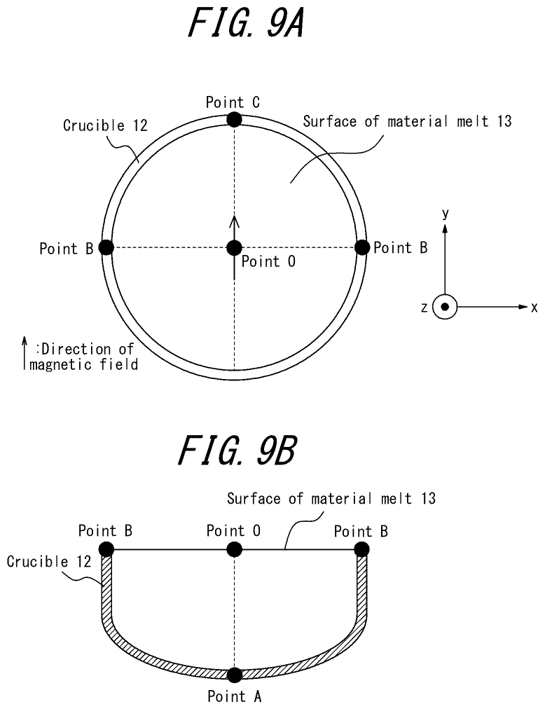

Furthermore, as illustrated in FIG. 9, it is preferable that the magnet 1 according to the present disclosure has, when M represents the magnetic flux density at the center O (0 mm, 0 mm, 0 mm) of the magnetic field neutral plane, a magnetic flux density of 0.58×M or greater at the point A (0 mm, 0 mm, −400 mm) and a magnetic flux density of 1.47×M or greater at the points B (400 mm, 0 mm, 0 mm). As a result, the variations in the oxygen concentration in the pulling direction of the single crystal can be suppressed, and the fluctuations in the pulling speed of the single crystal can also be suppressed, thereby enabling the production of defect-free single crystals. The details of the point A, the points B, and the magnetic field neutral plane will be described in detail later.

### (Method of Producing Single Crystal)

A method of producing a single crystal according to the present disclosure is a method of producing a single crystal by the Czochralski method using the single crystal production apparatus according to the present disclosure described above, the method comprising pulling up the single crystal while applying a horizontal magnetic field to a material melt by the magnet so that, when M represents a magnetic flux density at the center O (0 mm, 0 mm, 0 mm) of the magnetic neutral plane, the magnetic flux density is 0.58×M or greater at the point A (0 mm, 0 mm, −400 mm) and the magnetic flux density is 1.47×M or greater at the points B (400 mm, 0 mm, 0 mm).

As described above, when the single crystal production apparatus 10 according to the present disclosure is used, a magnetic field can be applied to the material melt 13 with the desired magnetic field distribution to produce single crystals with the desired characteristics. The present inventors have discovered that a single crystal with small variations in the oxygen concentration can be produced by applying an appropriate magnetic field distribution to the material melt 13 using the production apparatus 10 described above.

Specifically, the present inventors have discovered that by pulling up the single crystal while applying a horizontal magnetic field to a material melt by the magnet so that, when M represents a magnetic flux density at the center O (0 mm, 0 mm, 0 mm) of the magnetic neutral plane, as illustrated in FIG. 9, the magnetic flux density is 0.58×M or greater at the point A (0 mm, 0 mm, −400 mm) and the magnetic flux density is 1.47×M or greater at the points B (400 mm, 0 mm, 0 mm), the variations in the oxygen concentration in the pulling direction of the single crystal can be suppressed, and the fluctuations in the pulling speed of the single crystal can also be suppressed, thereby enabling the production of defect-free single crystals.

Note that, the “magnetic field neutral plane” described above refers to the plane that includes the centers of gravity of the coils 2 composing the magnet 1, and the “center of the magnetic field neutral plane” refers to the point where the magnetic field neutral plane intersects with the rotation axis of the crystal. The coils 2 are preferably arranged so that the levels of the centers of gravity of all coils 2 are the same and the magnetic field neutral plane is a horizontal plane.

When the magnet 1 is disposed in the single crystal production apparatus 10 and a single crystal is produced while a horizontal magnetic field is applied, the central axis of the magnet 1 generally coincides with the rotation axis of the crystal. In other words, the axis passing through the center of the magnet 1 according to the present disclosure and extending in the vertical direction can be regarded as the same as the rotation axis of the crystal. Accordingly, in general, the center O (0 mm, 0 mm, 0 mm) of the magnetic field neutral plane can be rephrased as the point where the magnetic field neutral plane intersects the axis passing through the center of the magnet 1 and extending in the vertical direction. In particular, when the magnet 1 is removed from the single crystal production apparatus, in other words, when only the magnet 1 is placed, the center of the magnetic field neutral plane O (0 mm, 0 mm, 0 mm) is the point where the magnetic field neutral plane intersects the axis passing through the center of the magnet 1 and extending in the vertical direction, i.e., the central axis of the magnet 1.

Furthermore, the points A and B are defined as follows. On the magnetic field neutral plane, the center of the magnetic field, which is the center of the magnetic field neutral plane, shall be defined as the origin O, the axis parallel to the direction of the magnetic field shall be defined as the y-axis, the axis perpendicular to the direction of the magnetic field shall be defined as x-axis, and the axis passing through the origin O and perpendicular to the magnetic field neutral plane shall be defined as the z-axis. At the time when the crystal starts to be pulled up, the point on the inside (inner surface) of the crucible 12 along the z-axis is the point A, and the points on the inside (inner surface) of the crucible 12 along the x-axis are the points B. When the magnetic neutral plane is a horizontal plane, the z-axis and the rotation axis of the crystal coincide.

The requirements for the magnetic flux density at the aforementioned points A and B can be achieved by aligning the magnetic field neutral plane and the level of the surface of the material melt 13 to the same level and setting the angle between the two coils to 90° or more.

In addition, the magnetic flux density at the point C (0 mm, 400 mm, 0 mm) on the y-axis, which is the same level as the points B and on the inside (inner surface) of the crucible 12, is preferably set to be smaller than the magnetic flux densities at the points B. This further suppresses fluctuations of the convection in the material melt 13.

The single crystal 16 described above is not limited as long as it can be produced by the CZ method, but a single crystal of silicon for semiconductors with small variations in the oxygen concentration can be suitably produced.

### EXAMPLES

Examples of the present disclosure will be described below, but the present disclosure is not limited to the examples.

### Example 1

A single crystalline silicon having a diameter of 310 mm was produced by using a single crystal production apparatus comprising a magnet with coils having a vertically elongated hollowed-out rectangular shape illustrated in FIG. 2. The coils having a vertically elongated hollowed-out rectangular shape were configured so that the level of the magnetic field neutral plane coincided the point A in FIG. 9B, and the four coils were arranged so that the angle between coils (the angle between two coils 2 disposed across the flux line at the center O of the magnetic field) was 60°. Each coil was configured to be a vertically elongated type and have the same shape, and the magnetic field neutral plane was a horizontal plane. The magnitudes and directions of the current to flow to the coils were adjusted to generate a magnetic field distribution with a magnetic flux density of 0.58 M at the point A and 1.43 M at the points B. In this condition, polycrystalline silicon, which was the raw material for silicon, was received in a crucible and molten, and then a seed crystal was dipped into the molten silicon. By pulling the seed crystal upward, single crystalline silicon was caused to grow beneath the seed crystal.

### Example 2

Single crystalline silicon was produced in the same manner as in Example 1. However, the level of the magnetic field neutral plane relative to the point A was changed so that the magnetic flux density at the point A was 0.64 times and the magnetic flux density at the point B was 2.23 times the magnetic flux density M at the center O of the magnetic field. All other conditions were the same as in Example 1.

### COMPARATIVE EXAMPLE

Single crystalline silicon was produced in the same manner as in Example 1. However, the level of the magnetic field neutral plane relative to the point A was changed so that the magnetic flux density at the point A was 0.53 times and the magnetic flux density at a point B was 1.03 times the magnetic flux density M at the center O of the magnetic field. All other conditions were the same as in Example 1.

### <Oxygen Concentration in Axial Direction of Single Crystal>

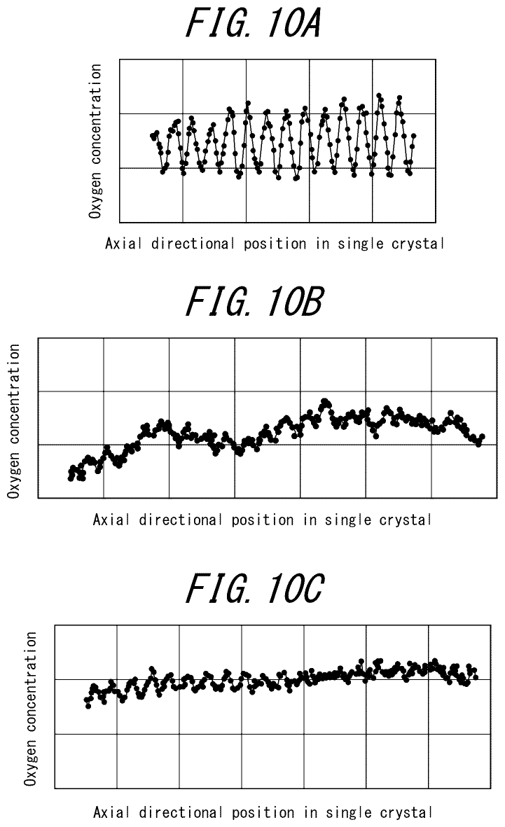

FIGS. 10A to 10C indicate the variations in the oxygen concentration in the axial direction of single crystalline silicon, where FIG. 10A pertains to Comparative Example, FIG. 10B pertains to Example 1, and FIG. 10C pertains to Example 2. Note that, in FIG. 10, the axial directional position in the single crystal and the oxygen concentration are normalized by respective given values. In Comparative Example indicated in FIG. 10A, the oxygen concentration varied significantly in the axial direction of the single crystal and did not fall within a specified oxygen concentration range. On the other hand, in Examples 1 and 2 illustrated in FIGS. 10B and 10C, the variations in the oxygen concentration were reduced compared to Comparative Example, and especially the variations in the oxygen concentration in Example 2 were reduced to about one-fifth of those in Comparative Example.

### <Fluctuations Over Time of Temperature at Solid-Liquid Interface>

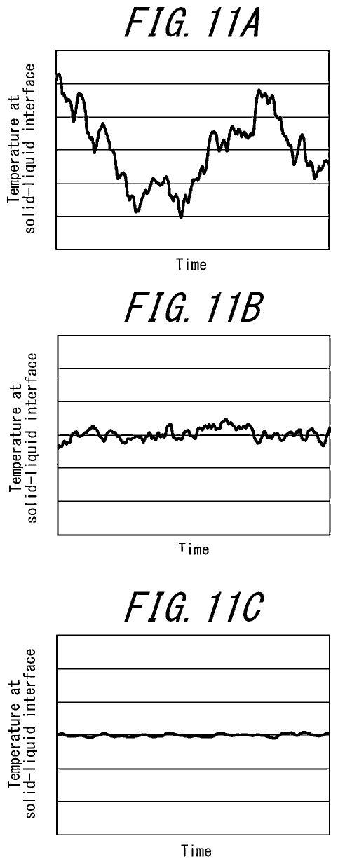

FIGS. 11A to 11C indicates the fluctuations over time of the temperature at the solid-liquid interface based on three-dimensional fluid simulations, where FIG. 11A pertains to Comparative Example, FIG. 11B pertains to Example 1, and FIG. 11C pertains to Example 2. In FIG. 11, the time and the temperature of the solid-liquid interface are normalized by respective given values. It was observed that in Comparative Example indicated in FIG. 11A, the fluctuations over time of the temperature of the solid-liquid interface were large, and the temperature fluctuations the caused significant fluctuations in the crystal pulling speed, leading to the inability to obtain defect-free single crystalline silicon. On the other hand, in Example 1 and Example 2 indicated in FIGS. 11B and 11C, respectively, it was observed that the fluctuations over time of the temperature of the solid-liquid interface were reduced compared to Comparative Example, and the fluctuations in the crystal pulling speed was minimized. Defect-free single crystalline silicon was thus obtained in both examples. Particularly, the fluctuations over time of the temperature at the solid-liquid interface in Example 2 were reduced to about one-fiftieth of those in Comparative Example.

### INDUSTRIAL APPLICABILITY

According to the present disclosure, it is possible to enhance the degree of freedom in the design of the magnetic field distribution even when the arrangement of coils composing a magnet for a single crystal production apparatus is restricted. Accordingly, the present disclosure is useful in the semiconductor wafer manufacturing industry.

### REFERENCE SIGNS LIST

1, 21 Magnet
2, 22 Coil
2a Opening
2b Outer surface
2c Inner surface
2d Outer periphery surface
2e Inner periphery surface
3 First portion
4 Second portion
5 Connection portion
10, 100 Single crystal production apparatus
11 Chamber
12 Crucible
13 Material melt
14 Heater
15 Crucible rotation mechanism
16 Single crystal
17 Seed crystal
18 Seed crystal holder
19 Wire rope
20 Wind-up mechanism

1. A magnet for a single crystal production apparatus that pulls up a single crystal while applying a horizontal magnetic field to a material melt for the single crystal received in a crucible, the magnet applying the horizontal magnetic field in the single crystal production apparatus, the magnet comprising:
four or more coils, a ratio of a height to a width of at least one of the four or more coils exceeding 1; and
a control unit that enables the four or more coils to generate magnetic fields independently of each other.

2. The magnet for a single crystal production apparatus according to claim 1, wherein the coil has a hollowed-out rectangular shape.

3. The magnet for a single crystal production apparatus according to claim 1, wherein the height is 600 mm or more.

4. The magnet for a single crystal production apparatus according to claim 1, wherein, when M represents a magnetic flux density at a center O (0 mm, 0 mm, 0 mm) of a magnetic neutral plane, the magnetic flux density is 0.58×M or greater at a point A (0 mm, 0 mm, −400 mm) and the magnetic flux density is 1.47×M or greater at a point B (400 mm, 0 mm, 0 mm).

5. A single crystal production apparatus, comprising a crucible for receiving a material melt for a single crystal and the magnet according to claim 1, which is arranged surrounding the crucible, the apparatus pulling up the single crystal while applying a horizontal magnetic field to the melt by the magnet.

6. A method of producing a single crystal by the Czochralski method using the single crystal production apparatus according to claim 5, the method comprising:
pulling up the single crystal while applying a horizontal magnetic field to the material melt by the magnet so that, when M represents a magnetic flux density at a center O (0 mm, 0 mm, 0 mm) of a magnetic neutral plane, the magnetic flux density is 0.58×M or greater at a point A (0 mm, 0 mm, −400 mm) and the magnetic flux density is 1.47×M or greater at a point B (400 mm, 0 mm, 0 mm).

7. The method of producing a single crystal according to claim 6, wherein the single crystal is a single crystalline silicon.

8. The magnet for a single crystal production apparatus according to claim 2, wherein the height is 600 mm or more.

9. The magnet for a single crystal production apparatus according to claim 2, wherein, when M represents a magnetic flux density at a center O (0 mm, 0 mm, 0 mm) of a magnetic neutral plane, the magnetic flux density is 0.58×M or greater at a point A (0 mm, 0 mm, −400 mm) and the magnetic flux density is 1.47×M or greater at a point B (400 mm, 0 mm, 0 mm).

10. The magnet for a single crystal production apparatus according to claim 3, wherein, when M represents a magnetic flux density at a center O (0 mm, 0 mm, 0 mm) of a magnetic neutral plane, the magnetic flux density is 0.58×M or greater at a point A (0 mm, 0 mm, −400 mm) and the magnetic flux density is 1.47×M or greater at a point B (400 mm, 0 mm, 0 mm).

11. The magnet for a single crystal production apparatus according to claim 8, wherein, when M represents a magnetic flux density at a center O (0 mm, 0 mm, 0 mm) of a magnetic neutral plane, the magnetic flux density is 0.58×M or greater at a point A (0 mm, 0 mm, −400 mm) and the magnetic flux density is 1.47×M or greater at a point B (400 mm, 0 mm, 0 mm).

12. A single crystal production apparatus, comprising a crucible for receiving a material melt for a single crystal and the magnet according to claim 2, which is arranged surrounding the crucible, the apparatus pulling up the single crystal while applying a horizontal magnetic field to the melt by the magnet.

13. A single crystal production apparatus, comprising a crucible for receiving a material melt for a single crystal and the magnet according to claim 3, which is arranged surrounding the crucible, the apparatus pulling up the single crystal while applying a horizontal magnetic field to the melt by the magnet.

14. A single crystal production apparatus, comprising a crucible for receiving a material melt for a single crystal and the magnet according to claim 4, which is arranged surrounding the crucible, the apparatus pulling up the single crystal while applying a horizontal magnetic field to the melt by the magnet.

15. A single crystal production apparatus, comprising a crucible for receiving a material melt for a single crystal and the magnet according to claim 8, which is arranged surrounding the crucible, the apparatus pulling up the single crystal while applying a horizontal magnetic field to the melt by the magnet.

16. A single crystal production apparatus, comprising a crucible for receiving a material melt for a single crystal and the magnet according to claim 9, which is arranged surrounding the crucible, the apparatus pulling up the single crystal while applying a horizontal magnetic field to the melt by the magnet.

17. A single crystal production apparatus, comprising a crucible for receiving a material melt for a single crystal and the magnet according to claim 10, which is arranged surrounding the crucible, the apparatus pulling up the single crystal while applying a horizontal magnetic field to the melt by the magnet.

18. A single crystal production apparatus, comprising a crucible for receiving a material melt for a single crystal and the magnet according to claim 11, which is arranged surrounding the crucible, the apparatus pulling up the single crystal while applying a horizontal magnetic field to the melt by the magnet.
